(19) United States
(12) Patent Application Publication
(10) Pub. No.: US 2023/0318319 A1
(43) Pub. Date: Oct. 5, 2023

(54) BATTERY DEVICE

(71) Applicant: DENSO CORPORATION, Kariya-city, Aichi-pref. (JP)

(72) Inventors: Takayuki TAKEUCHI, Kariya-city (JP); Yuuki HORI, Kariya-city (JP)

(73) Assignee: DENSO CORPORATION, Kariya-city, Aichi-pref. (JP)

(21) Appl. No.: 18/329,736

(22) Filed: Jun. 6, 2023

Related U.S. Application Data
(63) Continuation of application No. PCT/JP2022/004618, filed on Feb. 7, 2022.

(30) Foreign Application Priority Data
Mar. 23, 2021 (JP) 2021-049205

(51) Int. Cl. H02J 7/00; G01R 31/36; H01M 10/48; H01M 10/42; B60L 58/13; G01R 31/3835

(52) U.S. Cl. CPC H02J 7/0019; G01R 31/3648; H01M 10/486; H01M 10/425; B60L 58/13; G01R 31/3835; H01M 2010/4271; H01M 2220/20

(57) ABSTRACT

A battery device has a storage unit, a calculation unit, a level shifter, and an AD conversion unit. The storage unit stores battery information including a closed circuit voltage of a plurality of battery cells electrically connected to each other. The setting unit that sets an acquisition range of the closed circuit voltage based on the battery information. The level shifter and the AD conversion unit convert the closed circuit voltage into a digital signal within the acquisition range set by the calculation unit. The calculation unit changes the acquisition range when the closed circuit voltage is outside the acquisition range.

### CROSS REFERENCE TO RELATED APPLICATIONS

The present application is a continuation application of International Patent Application No. PCT/JP2022/004618 filed on Feb. 7, 2022, which designated the U.S. and claims the benefit of priority from Japanese Patent Application No. 2021-049205 filed on Mar. 23, 2021. The entire disclosures of all of the above applications are incorporated herein by reference.

### TECHNICAL FIELD

The disclosure provided herein relates to a battery device.

### BACKGROUND

A conceivable technique teaches a capacity adjustment device that equalizes the SOCs of a plurality of lithium secondary batteries.

### SUMMARY

According to an example, a battery device may have a storage unit, a calculation unit, a level shifter, and an AD conversion unit. The storage unit stores battery information including a closed circuit voltage of a plurality of battery cells electrically connected to each other. The setting unit that sets an acquisition range of the closed circuit voltage based on the battery information. The level shifter and the AD conversion unit convert the closed circuit voltage into a digital signal within the acquisition range set by the calculation unit. The calculation unit changes the acquisition range when the closed circuit voltage is outside the acquisition range.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a block diagram showing a battery device and an assembled battery;

FIG. 2 is a graph showing SOC and OCV characteristics;

FIG. 3 is a timing chart showing voltage detection;

FIG. 4 is a timing chart showing voltage detection;

FIG. 5 is a timing chart showing ground fault detection;

FIG. 6 is a timing chart showing power fault detection;

FIG. 7 is a flowchart illustrating voltage detection process;

FIG. 8 is a timing chart showing ground fault detection;

FIG. 9 is a timing chart showing power fault detection;

FIG. 10 is a timing chart showing ground fault detection;

FIG. 11 is a timing chart showing ground fault detection;

FIG. 12 is a timing chart showing power fault detection;

FIG. 13 is a timing chart showing ground fault detection; and

FIG. 14 is a timing chart showing power fault detection.

### DETAILED DESCRIPTION

The closed path voltage of lithium secondary batteries is used to equalize the SOCs of a plurality of lithium secondary batteries. Therefore, it is necessary to avoid a situation that the closed path voltage becomes undetectable.

An object of the present embodiments is to provide a battery device that suppresses the closed path voltage from becoming undetectable.

A battery device according to an aspect of the present embodiments includes:
a storage unit that stores battery information including a closed path voltage of a plurality of electrically connected battery cells;
a setting unit that sets an acquisition range of the closed path voltage based on the battery information; and
a conversion unit that converts the closed path voltage into a digital signal within the acquisition range set by the setting unit.

The setting unit changes the acquisition range when the closed path voltage is one of the upper limit value and the lower limit value of the acquisition range.

According to this, as a result of restrictively narrowing the acquisition range, it is suppressed that the closed path voltage cannot be detected.

The reference numerals in parentheses above indicate only a correspondence relationship with the configuration described in the embodiment to be described later, and do not limit the technical range in any way.

The following will describe embodiments for carrying out the present disclosure with reference to the drawings. In each of embodiments, parts/configurations corresponding to the elements described in the preceding embodiments are denoted by the same reference numerals, and redundant explanation may be omitted. When only a part of a configuration is described in an embodiment, another preceding embodiment may be applied to the other parts of the configuration.

When, in each embodiment, it is specifically described that combination of parts is possible, the parts can be combined. In a case where any obstacle does not especially occur in combining the parts of the respective embodiments, it is possible to partially combine the embodiments, the embodiment and the modification, or the modifications even when it is not explicitly described that combination is possible.

### First Embodiment

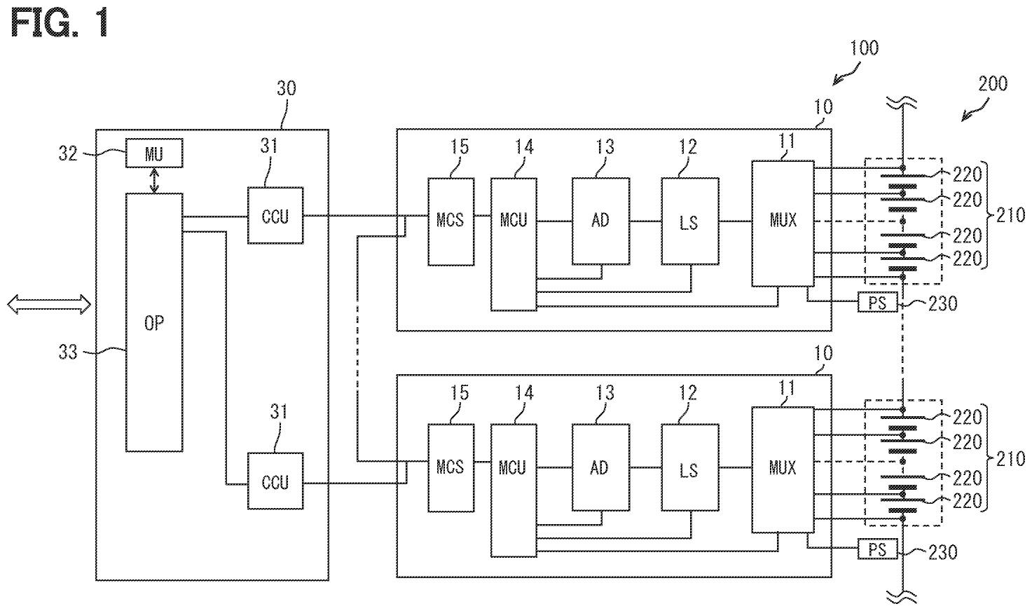

A first embodiment will be described with reference to FIGS. 1 to 8.

FIG. 1 shows a battery device 100 and an assembled battery 200. The battery device 100 and the assembled battery 200 are mounted on an electric vehicle such as a hybrid vehicle or an electric vehicle. The electric vehicles include passenger cars, buses, construction vehicles, agricultural machinery vehicles, and the like.

The battery device 100 monitors and controls the state of the assembled battery 200. The assembled battery 200 supplies electric power to various in-vehicle devices such as an electric motor that provides driving force to the electric vehicle.

(Assembled Battery)

The assembled battery 200 has a plurality of battery stacks 210. Each of the plurality of battery stacks 210 has a plurality of battery cells 220 electrically connected in series. As the battery cell 220, a secondary battery such as a lithium-ion secondary battery, a nickel-hydrogen secondary battery, or an organic radical battery can be employed. The output voltage of the battery cells 220 connected in series is the output voltage of the battery stack 210. In FIG. 1, a plurality of battery cells 220 included in one battery stack 210 are shown surrounded by dashed lines.

A plurality of battery stacks 210 are electrically connected in series or in parallel. In this embodiment, a plurality of battery stacks 210 are electrically connected in series. The output voltage of the assembled battery 200 is the sum of the output voltages of the plurality of battery stacks 210 connected in series. The power source electric power depending on this output voltage is supplied to various in-vehicle devices.

Each of the plurality of battery stacks 210 is provided with a physical quantity sensor 230 that detects the physical quantity of the battery cell 220. The physical quantities detected by the physical quantity sensor 230 include, for example, the temperature and the current of the battery cell 220.

The physical quantity detected by the physical quantity sensor 230 is used for estimating the SOC of each of the battery cell 220, the battery stack 210, and the assembled battery 200, and the like. The SOC is an abbreviation for state of charge. The SOC corresponds to the charge amount.

The SOC is reduced by supplying the above power source electric power to various in-vehicle devices. Also, the battery cell 220 self-discharges. Therefore, the SOC decreases even when the power source electric power is not supplied.

This decrease in the SOC is improved by supplying the charging power to the assembled battery 200 from a charging device such as an electric station disposed outside the vehicle, for example. The supply of charging the electric power from the charging device to the assembled battery 200 is controlled by the battery device 100. The battery device 100 controls the charging of the assembled battery 200 while transmitting and receiving a CPLT signal to and from the charging device via a wiring (not shown).

Note that the quality and environment of the plurality of battery cells 220 are not uniform. Therefore, the SOCs of the plurality of battery cells 220 may vary. This variation is improved by an equalization process, which will be described later.

<OCV, CCV, SOC>

The battery cell 220 has an internal resistance. Therefore, there is a difference of a voltage drop between the actual cell voltage according to the SOC of the battery cell 220 and the cell voltage detected by the monitor unit 10, and the voltage drop corresponds to the internal resistance and the current flowing through the battery cell 220.

Hereinafter, the actual cell voltage corresponding to the SOC of the battery cell 220 will be referred to as an open path voltage OCV as required. A cell voltage detected by the monitor unit 10 is indicated as a closed path voltage CCV. The internal resistance R is the resistance in the battery cell 220 and the actual current I is the current that actually flows through the battery cell 220. OCV is an abbreviation for Open Circuit Voltage. CCV is an abbreviation for Closed Circuit Voltage.

A relationship between the closed circuit voltage CCV and the open circuit voltage OCV is expressed as CCV=OCV±I×R. When the battery cell 220 is discharged, the above relationship is expressed as CCV=OCV−I×R. When the battery cell 220 is charged, the above relationship is expressed as CCV=OCV+I×R.

<Characteristics of SOC and OCV>

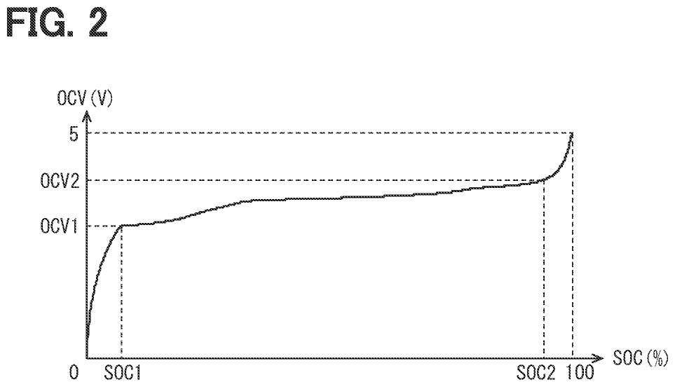

The battery cell 220 has SOC and OCV characteristics. FIG. 2 shows SOC and OCV characteristic data when the battery cell 220 is a lithium ion battery.

As shown in FIG. 2, in the over-discharge region where the SOC is close to 0%, the rate of change of OCV with respect to SOC is high. In the over-charge region where the SOC is close to 100%, the rate of change of OCV with respect to SOC is high.

On the other hand, in the charge/discharge region between the over-discharge region and the over-charge region, the rate of change of OCV with respect to SOC is low. The battery cell 220 is mainly used in this charge/discharge region. In FIG. 2, as an example, the values of the SOC and the OCV between the over-discharge region and the charge/discharge region are expressed as SOC1 and OCV1. The values of the SOC and the OCV between the charge/discharge region and the over-charge region are denoted as SOC2 and OCV2.

The characteristic data shown in FIG. 2 are temperature dependent. Therefore, the rate of change of OCV with respect to SOC changes depending on the temperature. Along with this, the values of SOC1, SOC2, OCV1 and OCV2 also change.

<Battery Device>

The battery device 100 has a monitor unit 10 and a control unit 30. The battery device 100 has the same number of monitor units 10 as the battery stacks 210. The plurality of monitor units 10 detect battery information related to the state of each of the plurality of battery stacks 210.

The control unit 30 acquires battery information detected by the multiple monitor units 10. The control unit 30 also acquires vehicle information input from various other ECUs and various sensors (not shown). When a charging device is connected to the electric vehicle, the control unit 30 acquires charging information input from the charging device. The input of the vehicle information and charging information to the control unit 30, and the output of the processing result of the control unit 30 to various ECUs, the charging device and the like are indicated by white arrows in FIG. 1.

The control unit 30 determines the state of the assembled battery 200 based on the acquired information. At the same time, the control unit 30 executes processing for the assembled battery 200. The processing for the assembled battery 200 includes, for example, charge/discharge of the assembled battery 200, equalization processing for equalizing the SOCs of the plurality of battery cells 220 included in the assembled battery 200, and the like.

<Monitor Unit>

Each of the plurality of monitor units 10 is individually provided for each of the plurality of battery stacks 210. One monitor unit 10 detects the inter-terminal voltage (i.e., the closed circuit voltage) between the positive and negative electrodes of each of the plurality of battery cells 220 included in one battery stack 210. Also, the monitor unit 10 acquires the physical quantity detected by the physical quantity sensor 230. The monitor unit 10 executes processing based on instruction signals input from the control unit 30.

As shown in FIG. 1, the monitor unit 10 has a multiplexer 11, a level shifter 12, an AD conversion unit 13, a monitor control unit 14 and a monitor communication unit 15. In the drawing, the multiplexer 11 is written as MUX. The level shifter 12 is written as LS. The AD conversion unit 13 is written as AD. The monitor control unit 14 is written as MCU. The monitor communication unit 15 is written as MCS.

The multiplexer 11 is connected to the positive and negative electrodes of each of the plurality of battery cells 220 included in one battery stack 210. As a result, the multiplexer 11 receives the closed circuit voltages of the plurality of battery cells 220.

Also, the multiplexer 11 is connected to the physical quantity sensor 230. Thereby, the physical quantity is input to the multiplexer 11.

The multiplexer 11 sequentially selects and detects a plurality of input closed circuit voltages. The multiplexer 11 sequentially outputs the detected closed circuit voltages to the level shifter 12. The multiplexer 11 also sequentially selects and detects a plurality of input physical quantities. The multiplexer 11 also sequentially outputs the detected physical quantities to the level shifter 12.

The level shifter 12 includes an operational amplifier and multiple feedback circuits connected in parallel between an input terminal and an output terminal of the operational amplifier. This feedback circuit includes a switch and a capacitor connected in series. The capacitances of the capacitors included in the multiple feedback circuits may be the same or different.

The switches of the plurality of feedback circuits of the level shifter 12 are selectively controlled to turn on and off by the monitor control unit 14. As a result, the number of capacitors connected between the input terminal and the output terminal of the operational amplifier changes. The capacitance between the input terminal and the output terminal of the operational amplifier changes. In addition, the resistance between the input terminal and the output terminal of the operational amplifier changes. As a result, the gain and the offset of the level shifter 12 are controlled.

The analog signals of the closed circuit voltage and the physical quantity whose gain and offset are adjusted is input from the level shifter 12 to the AD conversion unit 13. The AD conversion unit 13 has a clamp circuit for limiting the input range. This clamp circuit is controlled by the monitor control unit 14. The input range of the AD conversion unit 13 is thereby controlled.

By limiting the input range of the AD conversion unit 13 and adjusting the gain and the offset of the level shifter 12, the voltage range of the analog signal converted from analog to digital by the AD conversion unit 13 is controlled. The voltage ranges of the closed circuit voltage and the physical quantity that are analog-to-digital converted by the AD conversion unit 13 are controlled. As a result, the acquisition ranges of the closed circuit voltage and the physical quantity are controlled. Note that it is not necessary to particularly control the acquisition range of the physical quantity. The level shifter 12 and the AD conversion unit 13 correspond to the converter.

The AD conversion unit 13 intermittently samples continuous analog signals. Then, the AD conversion unit 13 quantizes the sampled values and converts them into discrete digital signals. Due to such conversion, there may be an error (i.e., the quantization error) between the analog signal and the digital signal.

This quantization error becomes smaller as the number of quantization bits of the AD conversion unit 13 increases. However, the number of quantization bits is fixed. Therefore, for example, when the acquisition range of the closed circuit voltage is between 0.0V and 5.0V, the resolution of the AD conversion unit 13 is the value obtained by dividing this range between 0.0V and 5.0V by the number of quantization bits.

On the other hand, for example, when the acquisition range of the closed circuit voltage is between 3.0 V and 3.5 V, which is 1/10 of the above range, the resolution of the AD conversion unit 13 is the value obtained by dividing the range between 3.0 V and 3.5 V by the number of quantization bits. In this case, the resolution of the AD conversion unit 13 is increased by about ten times. By limiting the acquisition range in this way, the detection accuracy of the closed circuit voltage is improved.

The monitor control unit 14 has a processor and a non-transitional tangible storage medium that non-transitory stores a program readable by the processor. A digital signal input from the AD conversion unit 13 and an instruction signal input from the control unit 30 are stored in this non-transitory tangible storage medium. The processor of the monitor control unit 14 controls the multiplexer 11, the level shifter 12, and the AD conversion unit 13 based on the instruction signal.

The instruction signal input to the monitor control unit 14 includes the acquisition range of the closed circuit voltage of the battery cell 220 as a detection target. The monitor control unit 14 controls the gain and the offset of the level shifter 12 when the multiplexer 11 selects the closed circuit voltage as the detection target. The monitor control unit 14 limits the input range of the AD conversion unit 13. This controls the acquisition range of the closed circuit voltage.

The digital signals of the closed circuit voltage and the physical quantity are input to the monitor communication unit 15. The monitor communication unit 15 outputs this digital signal to the control unit 30.

<Control Unit>

As shown in FIG. 1, the control unit 30 has a control communication unit 31, a storage unit 32 and a calculation unit 33. In the drawing, the control communication unit 31 is denoted as CCU. The storage unit 32 is referred to as MU. The calculation unit 33 is referred to as OP. The calculation unit 33 corresponds to the setting unit.

Various information is input to the control communication unit 31. This information includes the closed circuit voltage and the physical quantity acquired by the monitor unit 10. In addition, this information includes vehicle information and charging information. The vehicle information includes the running state of the electric vehicle and the current time. The charging information includes charging electric power.

Note that vehicle information and charging information may be input to a communication unit (not shown). And when the control unit 30 has RTC, the present time does not need to be included in the vehicle information. RTC stands for Real Time Clock.

The storage unit 32 is a non-transitory tangible storage medium that non-transitory stores programs that can be read by a computer or a processor. The storage unit 32 includes a volatile memory and a nonvolatile memory. Various information input to the control communication unit 31 and processing results of the calculation unit 33 are stored in the storage unit 32.

In addition, the storage unit 32 stores in advance programs and reference values for the calculation unit 33 to perform calculation processing. The reference values include, for example, the temperature dependence of SOC and OCV characteristic data of various secondary batteries, an equalization determination value for determining execution of equalization processing, manufacturing dates of the plurality of battery cells 220, and deterioration determination value, and the like.

The calculation unit 33 has a processor. The calculation unit 33 stores various information input to the control communication unit 31 in the storage unit 32. The calculation unit 33 executes various calculation processes based on the information stored in the storage unit 32. An electrical signal including the result of this calculation processing is output to the monitor unit 10 via the control communication unit 31. An electric signal including the result of the calculation processing is output to various ECUs and the charging device via the control communication unit 31 or a communication unit (not shown).

As a specific example of the calculation process, the calculation unit 33 estimates the SOC of the battery cell 220 based on the information stored in the storage unit 32. The calculation unit 33 generates an instruction signal for instructing the operation of the monitor unit 10 based on the estimated SOC and the information stored in the storage unit 32. This instruction signal includes the acquisition range of the closed circuit voltage of the battery cell 220 as the detection target. Note that if the battery information for estimating the SOC is not stored in the storage unit 32, the calculation unit 33 sets the acquisition range of the closed circuit voltage to a possible range of the closed circuit voltage of the battery cell 220.

In addition to determining the acquisition range of the closed circuit voltage, the calculation unit 33 determines execution of an equalization process for reducing variations in the SOCs of the plurality of battery cells 220. The calculation unit 33 outputs an instruction signal including equalization processing for each of the plurality of battery stacks 210 to the monitor unit 10.

The calculation unit 33 calculates the difference between the maximum value and the minimum value of the closed circuit voltage input from the monitor unit 10. When this difference exceeds the equalization determination value, the calculation unit 33 determines to execute the equalization process. This equalization process may be performed, for example, only in the battery stack 210 in which at least one of the maximum value and the minimum value of the closed circuit voltage is detected. The equalization process may be performed on all battery stacks 210.

Although not clearly shown in the drawing, the monitor unit 10 has a plurality of switches that bridge a plurality of wires connecting the multiplexer 11 and the positive and negative electrodes of the plurality of battery cells 220, respectively. The monitor control unit 14 selectively controls the plurality of switches between the energization state and the cut-off state based on the instruction signal input from the calculation unit 33. As a result, the battery cell 220 with a relatively high SOC among the plurality of electrically connected battery cells 220 is discharged. Conversely, a battery cell 220 with relatively low SOC is charged. As a result, the SOCs of the plurality of battery cells 220 are equalized.

<Acquisition of Closed Circuit Voltage>

Due to the SOC and OCV characteristics of the battery cell 220 shown in FIG. 2, when the SOC drops due to discharge, the OCV also drops. Along with this, the closed circuit voltage CCV of the battery cell 220 also decreases. Conversely, when the SOC increases due to the supply of charging electric power from the charging device, the closed circuit voltage of battery cell 220 also increases.

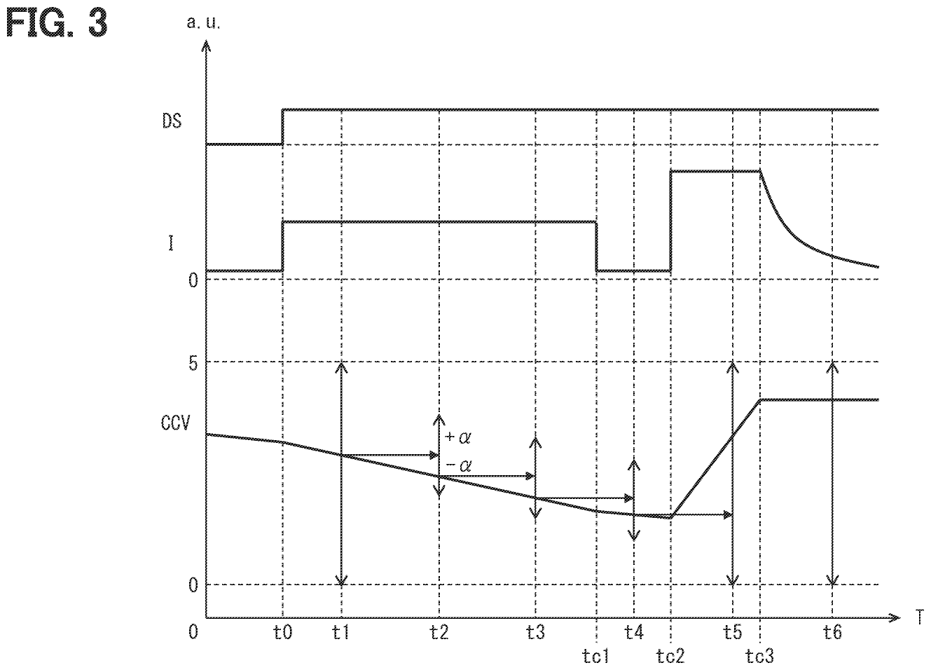

FIG. 3 shows the time change of the closed circuit voltage. The vertical axis is an arbitrary unit. The horizontal axis is time. The arbitrary unit is indicated by a. u. The time is indicated by T.

In addition to the closed circuit voltage, FIG. 3 shows the driving state of the battery device 100, the actual current flowing through the assembled battery 200, and the closed circuit voltage of one battery cell 220. The driving state of the battery device 100 is described as DS. For the sake of simplicity, the behavior of the closed circuit voltage of the battery cell 220 and the behavior of the closed circuit voltage of the assembled battery 200 shown in the drawings are assumed to be the same. In order to clarify the behavior, the drawing shows that the closed circuit voltage of the battery cell 220 changes significantly in a short time.

In the initial state at time 0, the battery device 100 is in a non-driving state. The storage unit 32 does not store battery information such as the closed circuit voltage and the physical quantity. The system main relay that controls the conduction state between the assembled battery 200 and various in-vehicle devices is in the cutoff state. Therefore, no current is substantially flowing through the assembled battery 200. The closed circuit voltage of the battery cell 220 has a value in the charge/discharge region.

Even when no current is flowing through the battery cell 220, the SOC of the battery cell 220 decreases due to self-discharge. Therefore, in the initial state of time 0, the closed circuit voltage of the battery cell 220 tends to decrease in a small amount.

At time t0, the battery device 100 changes from the non-driving state to the driving state. The system main relay changes from the cutoff state to the energization state. As a result, the supply of power source electric power from the assembled battery 200 to various in-vehicle devices is started. The actual current begins to flow in the assembled battery 200. The rate of decrease in the SOC of the battery cell 220 increases. Along with this configuration, the rate of decrease in the closed circuit voltage of the battery cell 220 also increases.

At time t1, the calculation unit 33 acquires the closed circuit voltage of the battery cell 220. At this time, the battery information is not stored in the storage unit 32. Therefore, the calculation unit 33 sets the acquisition range of the closed circuit voltage at the time t1 to a possible range that the battery cell 220 can take. That is, the calculation unit 33 sets the acquisition range of the closed circuit voltage between 0.0V and 5.0V.

At time t2, the calculation unit 33 again acquires the closed circuit voltage of the battery cell 220. At this time, the calculation unit 33 determines the center value of the acquisition range of the closed circuit voltage at the time t2 based on the closed circuit voltage of the battery cell 220 acquired at the time t1. Further, the calculation unit 33 determines the range width a of the acquisition range of the closed circuit voltage.

The acquisition range is indicated by the width of the solid double-ended arrow shown in FIG. 3. The difference between the center value and the upper or lower limit value of the acquisition range is set to the range width a. The range width a is a value greater than the detection error of the closed circuit voltage. The range width a is a value smaller than half of the difference between the OCV1 and the OCV2 shown in FIG. 2. The difference between the center value and the upper limit value and the difference between the center value and the lower limit value may be the same or different. In this embodiment, the range width a is a fixed value. The range width a is pre-stored in the storage unit 32. As such, the acquisition range is determined substantially based on the closed circuit voltage. The calculation unit 33 sets a limited acquisition range based on the range width a and the acquired closed circuit voltage. The calculation unit 33 sets the acquisition range at time t2 between 2.8V and 3.2V, for example. The calculation unit 33 acquires the closed circuit voltage detected by the monitor unit 10 in the acquisition range at this time t2.

Strictly speaking, since the battery device 100 performs a calculation process, the timing of determining the acquisition range and the timing of acquiring the closed circuit voltage around time t2 are not the same. The determination timing is before the acquisition timing. However, the difference between these two timings is small. Therefore, these two timings are substantially regarded as the same and described.

The calculation unit 33 acquires the closed circuit voltage at the acquisition cycle. This acquisition cycle is an expected time interval in which the SOC of the battery cell 220 does not suddenly change unless the charge or discharge state of the battery cell 220 suddenly changes due to rapid charging or the like. The acquisition cycle is a time interval in which it is expected that the amount of change in the closed circuit voltage of the battery cell 220 does not exceed the range width a. When the acquisition cycle elapses from the time t1, the time becomes t2.

At time t3 after the acquisition cycle has elapsed from time t2, the calculation unit 33 determines the acquisition range of the closed circuit voltage based on the closed circuit voltage at time t2. The calculation unit 33 sets the acquisition range at time t3 between 2.6V and 3.0V, for example. Then, the calculation unit 33 acquires the closed circuit voltage of the battery cell 220 detected by the monitor unit 10 in this acquisition range.

When the time t3 changes to the time tc1, the driving state of the vehicle changes. The actual current is reduced. Along with this configuration, the reduction rate of the closed circuit voltage is also reduced.

At time t4 after the acquisition cycle has elapsed from time t3, the calculation unit 33 determines the acquisition range of the closed circuit voltage based on the closed circuit voltage at time t3. The calculation unit 33 sets the acquisition range at time t4 between 2.4V and 2.8V, for example. Then, the calculation unit 33 acquires the closed circuit voltage of the battery cell 220 detected by the monitor unit 10 in this acquisition range. As shown in FIG. 3, even if the reduction rate of the closed circuit voltage decreases at time tc1, in this example, the closed circuit voltage detected at time t4 is within the acquisition range.

At tc2 elapsed from time t4, the charging device is connected to the electric vehicle. The assembled battery 200 is rapidly charged by the charging device. As a result, the actual current rises sharply. The calculation unit 33 acquires such information from vehicle information or charging information. At this time, the calculation unit 33 sets the acquisition range of the closed circuit voltage to a possible range that the battery cell 220 can take.

At time t5 after the acquisition period has passed from time t4, the calculation unit 33 acquires the closed circuit voltage of the battery cell 220 detected by the monitor unit 10 within the acquisition range set to the possible range of the closed circuit voltage. Due to the change in the acquisition range, as shown in FIG. 3, even when the closed circuit voltage suddenly rises from the time tc2, the closed circuit voltage detected at the time t5 is within the acquisition range.

When the time t5 changes to the time tc3, the output voltage of the assembled battery 200 reaches the target voltage. When detecting this, the calculation unit 33 terminates the rapid charging by the charging device. The calculation unit 33 causes the charging device to perform full charging.

The amount of current supply differs between the quick charge and the full charge. The quick charge has a larger supply current than the full charge.

As described above, there is a difference of the voltage drop of I×R between the closed circuit voltage CCV and the open circuit voltage OCV. During the charging, an expression of “CCV=OCV+I×R” is established. Therefore, even if the maximum output voltage of the assembled battery 200 is detected as the closed circuit voltage CCV, the open circuit voltage OCV does not reach the maximum output voltage. The SOC of the assembled battery 200 has not reached the full charge capacity.

The above target voltage is a value based on the maximum output voltage of the assembled battery 200. When the calculation unit 33 determines that the output voltage of the assembled battery 200 has reached the target voltage, it causes the charging device to perform full charging. In full charging, the charging power is supplied to the assembled battery 200 while maintaining the output voltage of the assembled battery 200 at the target voltage in order to bring the SOC of the assembled battery 200 closer to the full charge amount with avoiding over-charging. The target voltage and the maximum output voltage are stored in advance in the storage unit 32.

At time t6 after the acquisition period has passed from time t5, the calculation unit 33 acquires the closed circuit voltage of the battery cell 220 detected by the monitor unit 10 within the acquisition range set to the possible range of the battery cell 220. At this time, it may be expected that the output voltage of the assembled battery 200 has reached the target voltage. Therefore, the closed circuit voltage may be detected in the acquisition range based on this target voltage.

<Reset Acquisition Range>

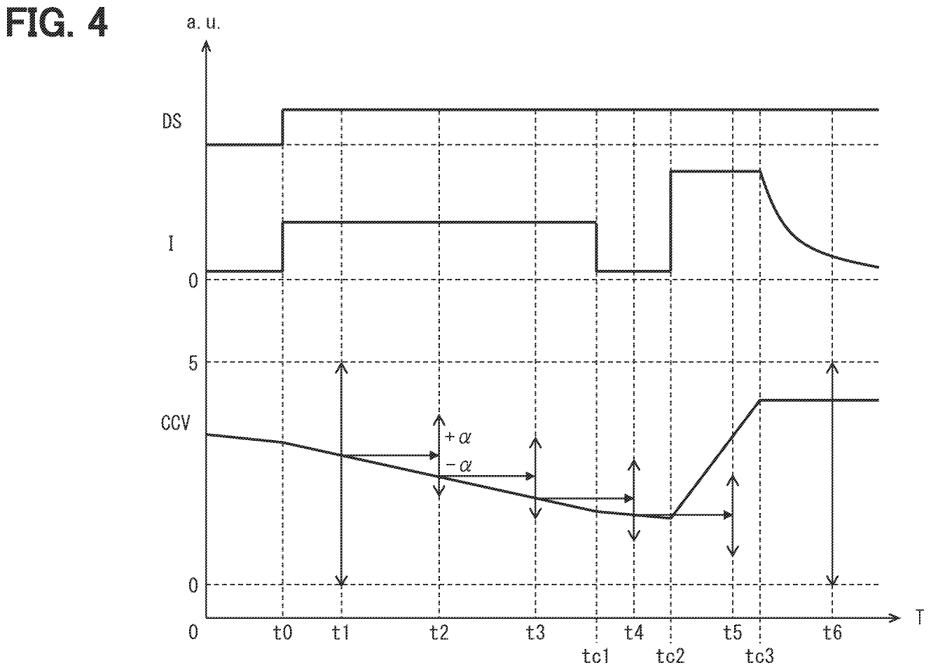

FIG. 3 shows an example in which the closed circuit voltage is detected within the acquisition range. However, it may happen that the closed circuit voltage is not detected within the acquisition range, for example as shown in FIGS. 4 to 6.

In the example shown in FIG. 4, the calculation unit 33 sets the acquisition range of the closed circuit voltage at time t5 based on the closed circuit voltage detected at time t4 without considering rapid charging of the assembled battery 200. With such settings, the closed circuit voltage is outside the acquisition range due to rapid charging. The closed circuit voltage detected by the monitor unit 10 becomes the upper limit of the acquisition range. The calculation unit 33 acquires this upper limit value.

When the upper limit value of the acquisition range is acquired in this manner, the calculation unit 33 resets the acquisition range of the closed circuit voltage to a possible range that the closed circuit voltage can take. By expanding the acquisition range in this way, it becomes possible to detect the closed circuit voltage at time t6.

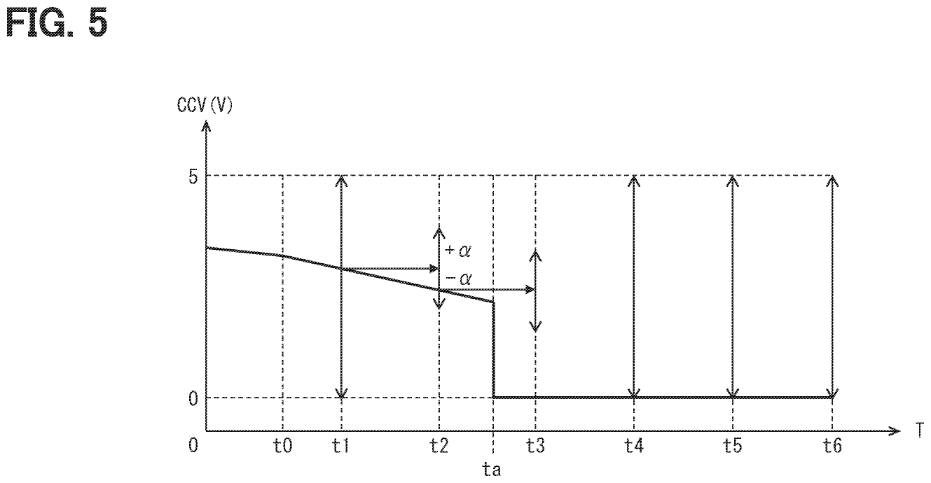

In the example shown in FIG. 5, the calculation unit 33 sets the acquisition range of the closed circuit voltage at time t3 based on the closed circuit voltage acquired at time t2. However, if a ground fault occurs at time to between time t2 and time t3, the closed circuit voltage detected by monitor unit 10 at time t3 is out of the acquisition range. The closed circuit voltage acquired by the calculation unit 33 becomes the lower limit value of the acquisition range.

When the lower limit value of the acquisition range is acquired in this manner, the calculation unit 33 resets the acquisition range of the closed circuit voltage to a possible range that the closed circuit voltage can take. By expanding the acquisition range in this way, it becomes possible to detect the closed circuit voltage at time t4.

If the ground fault is not temporary, the monitor unit 10 detects 0.0 V at times t3, t4, t5, and t6 after time ta, as shown in FIG. 5. The calculation unit 33 acquires 0.0V multiple times. When the number of acquisitions of 0.0 V is equal to or greater than the failure determination value, the calculation unit 33 determines that a ground fault has occurred. In this embodiment, the failure determination value is set to 3 times. Note that the value of the failure determination value is not particularly limited. A failure determination value is stored in the storage unit 32.

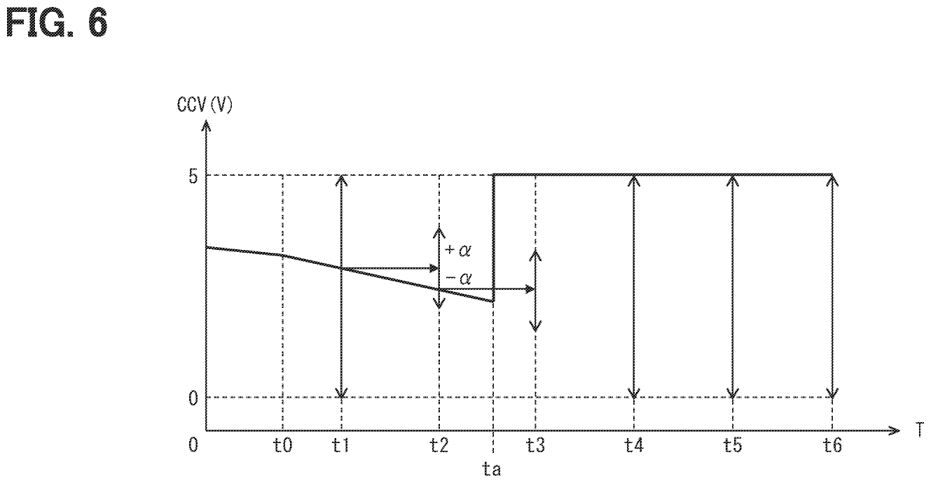

In the example shown in FIG. 6, the calculation unit 33 sets the acquisition range of the closed circuit voltage at time t3 based on the closed circuit voltage acquired at time t2. However, if a power fault occurs at time ta between time t2 and time t3, the closed circuit voltage detected by monitor unit 10 at time t3 is out of the acquisition range. The closed circuit voltage acquired by the calculation unit 33 becomes the upper limit value of the acquisition range.

When the upper limit value of the acquisition range is acquired in this way, the calculation unit 33 resets the acquisition range of the closed circuit voltage to a possible range that the closed circuit voltage can take, as described with reference to FIGS. 4 and 5.

If the power fault is not temporary, the monitor unit 10 detects 5.0 V at times t3, t4, t5, and t6 after time ta, as shown in FIG. 6. The calculation unit 33 acquires 5.0V multiple times. When the number of acquisitions of 5.0 V is equal to or greater than the failure determination value, the calculation unit 33 determines that a power fault has occurred.

<Voltage Detection Processing>

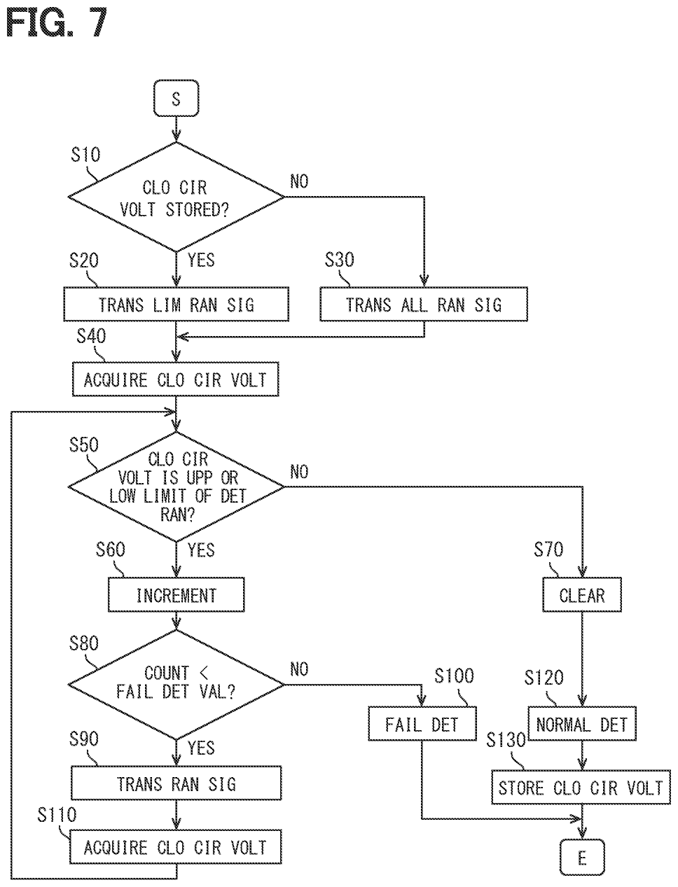

Next, the voltage detection processing of the calculation unit 33 will be described with reference to FIG. 7. The calculation unit 33 executes this voltage detection process as a cycle task. The execution interval of this voltage detection process corresponds to the acquisition period described above.

In step S10, the calculation unit 33 determines whether or not the closed circuit voltage is stored in the storage unit 32. When the closed circuit voltage is stored in the storage unit 32, the calculation unit 33 proceeds to step S20. If the closed circuit voltage is not stored in the storage unit 32, the calculation unit 33 proceeds to step S30.

When proceeding to step S20, the calculation unit 33 calculates the acquisition range of the closed circuit voltage based on the closed circuit voltage stored in the storage unit 32 and the range width a. The calculation unit 33 stores this acquisition range in the storage unit 32. Then, the calculation unit 33 transmits an instruction signal including the limited acquisition range to the monitor unit 10 as a limited range signal. After this process, in the calculation unit 33, the process proceeds to step S40.

When proceeding to step S40, the calculation unit 33 acquires the closed circuit voltage detected by the monitor unit 10. After this process, in the calculation unit 33, the process proceeds to step S50.

When proceeding to step S50, the calculation unit 33 determines whether or not the closed circuit voltage is the upper limit value or the lower limit value of the acquisition range. That is, the calculation unit 33 determines whether or not the closed circuit voltage is a value excluding the upper limit value and the lower limit value of the acquisition range. If the closed circuit voltage is the upper limit value or the lower limit value of the acquisition range, the calculation unit 33 proceeds to step S60. When the closed circuit voltage is a value excluding the upper limit value and the lower limit value of the acquisition range, the calculation unit 33 proceeds to step S70.

When proceeding to step S60, the calculation unit 33 increments its own counter by one. After this process, in the calculation unit 33, the process proceeds to step S80.

When proceeding to step S80, the calculation unit 33 determines whether or not the value of the counter is smaller than the failure determination value. The failure determination value of this embodiment is 3. If the counter value is smaller than the failure determination value, the calculation unit 33 proceeds to step S90. When the value of the counter is equal to or greater than the failure determination value, the calculation section 33 proceeds to step S100.

When proceeding to step S90, if the limited range signal has been transmitted in step S20, the calculation unit 33 sends an instruction signal including an acquisition range different from the acquisition range included in the limited range signal to the monitor unit 10 as a range signal. In the case of this embodiment, the calculation unit 33 causes the range signal to include the possible range of the closed circuit voltage. If a full-range signal, which will be described later, has been transmitted in step S30, the calculation unit 33 transmits an instruction signal equivalent to that to the monitor unit 10. Alternatively, the calculation unit 33 stops outputting the instruction signal. After this process, in the calculation unit 13, the process proceeds to step S110.

When proceeding to step S110, the calculation unit 33 acquires the closed circuit voltage detected by the monitor unit 10. After this process, the calculation unit 110 returns to the step S50.

When a ground fault or a power fault occurs as shown in FIGS. 5 and 6, the calculation unit 33 repeats steps S50, S60, S80, S90, and S110. It is repeated that the closed circuit voltage becomes the upper limit value or the lower limit value of the acquisition range. As a result, the value of the counter becomes equal to or greater than the failure determination value.

When the value of the counter does not exceed the failure determination value and the closed circuit voltage is stored in the storage unit 32, the calculation unit 33 estimates the SOC based on the stored closed circuit voltage. Then, the calculation unit 33 executes calculation processing based on the estimation result.

When it is determined in step S80 that the value of the counter is equal to or greater than the failure determination value and the process proceeds to step S100, the calculation unit 33 determines that a failure such as a ground fault or a power fault has occurred. Then, the calculation unit 33 terminates the voltage detection process.

Returning the flow, when it is determined in step S50 that the closed circuit voltage is neither the upper limit value nor the lower limit value of the acquisition range and the process proceeds to step S70, the calculation unit 33 clears the counter. The calculation unit 33 sets the value of the counter to zero. Then, in the calculation unit 33, the process proceeds to step S120.

When proceeding to step S120, the calculation unit 33 determines that the battery cell 220 is normal. Then, in the calculation unit 33, the process proceeds to step S130.

When proceeding to step S130, the calculation unit 33 stores the acquired closed circuit voltage in the storage unit 32. Then, the calculation unit 33 terminates the voltage detection process.

Returning the flow, when it is determined in step S10 that the closed circuit voltage is not stored in the storage unit 32 and the process proceeds to step S30, the calculation unit 33 transmits the instruction signal including the possible acquisition range of the closed circuit voltage to the monitor unit 10 as a full range signal. After this process, in the calculation unit 33, the process proceeds to step S40.

The voltage detection process will be described based on FIG. 6, and at time t1, the calculation unit 33 executes steps S30 and S130. The calculation unit 33 detects the closed circuit voltage within a possible acquisition range and stores the closed circuit voltage in the storage unit 32.

At time t2, the calculation unit 33 executes steps S20 and S130. The calculation unit 33 detects the closed circuit voltage in a limited acquisition range and stores the closed circuit voltage in the storage unit 32.

After time t3, the calculation unit 33 repeatedly executes steps S50, S60, S80, S90, and S110. Then, the calculation unit 33 executes step S100. The calculation unit 33 repeatedly acquires the closed circuit voltage while changing the acquisition range. Then, the calculation unit 33 performs failure determination.

<Operations and Effects>

As described above, when the closed circuit voltage is outside the acquisition range, the calculation unit 33 changes the acquisition range of the closed circuit voltage. The calculation unit 33 changes the acquisition range so that the closed circuit voltage is detected. The calculation unit 33 of the present embodiment changes the acquisition range to a possible acquisition range of the closed circuit voltage.

According to this, as a result of narrowing the acquisition range, it is suppressed that the closed circuit voltage cannot be detected.

For example, the calculation unit 33 changes the acquisition range of the closed circuit voltage from a possible acquisition range of 0.0V to 5.0V to a limited acquisition range of 3.0V to 3.5V. In this limited acquisition range, the analog closed circuit voltage is converted into a digital signal by the AD conversion unit 13. This reduces the quantization error of the AD conversion unit 13. Detection accuracy of the closed circuit voltage is improved.

The calculation unit 33 determines that a failure has occurred when the number of acquisitions of the lower limit value or the upper limit value of the acquisition range of the closed circuit voltage is equal to or greater than the failure determination value. Specifically, when the number of acquisitions of 0.0 V is 3 or more, the calculation unit 33 determines that a ground fault has occurred. When the number of acquisitions of 5.0 V is 3 or more, the calculation unit 33 determines that a power fault has occurred.

This suppresses erroneous determination of failure. A ground fault and a power fault can be separately detected.

### Second Embodiment

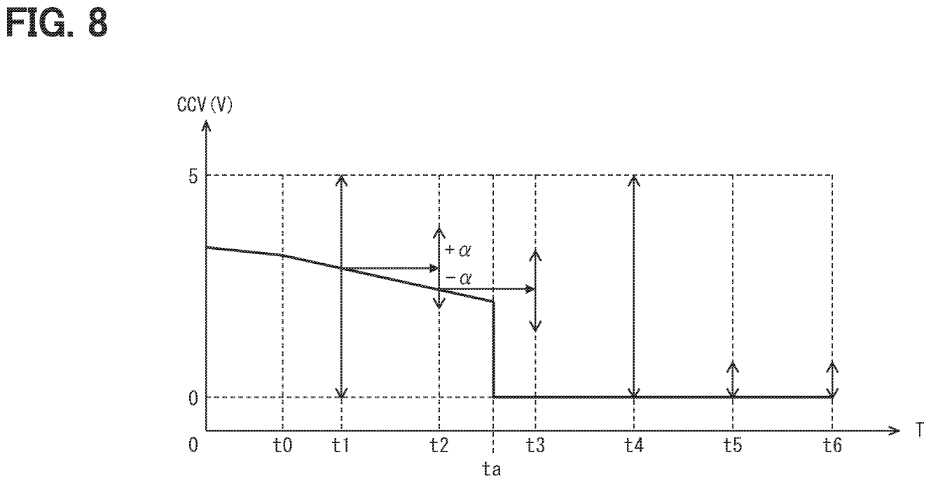

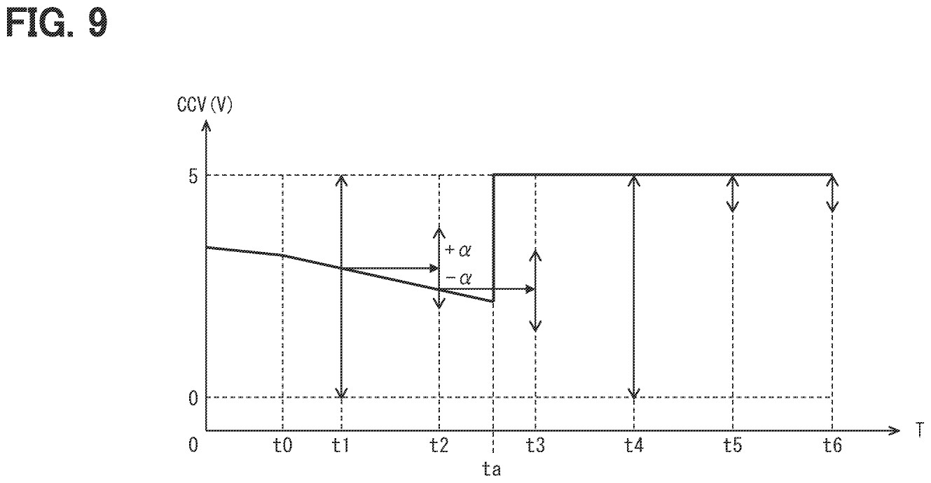

Next, a second embodiment will be described with reference to FIGS. 8 and 9.

In the first embodiment, when the closed circuit voltage of the upper limit value or the lower limit value of the acquisition range is acquired, the calculation unit 33 resets the acquisition range of the closed circuit voltage to a possible range of the closed circuit voltage. Then, an example has been shown in which the acquisition of the closed circuit voltage is continued within a possible range. On the other hand, in this embodiment, when the closed circuit voltage of the upper limit value or the lower limit value is acquired in the possible range, the calculation unit 33 narrows the acquisition range to the vicinity of the acquired closed circuit voltage.

As shown in FIG. 8, when the closed circuit voltage of the lower limit value is acquired in the possible range that the closed circuit voltage can take, the calculation unit 33 sets the acquisition range of the closed circuit voltage to the vicinity including the closed circuit voltage. The calculation unit 33 sets the acquisition range to around 0.0V. The calculation unit 33 sets the width of the acquisition range to a value smaller than the range width a stored in the storage unit 32. Thereby, a ground fault can be detected with high accuracy.

As shown in FIG. 9, when the closed circuit voltage of the upper limit value is acquired in the possible range that the closed circuit voltage can take, the calculation unit 33 sets the acquisition range of the closed circuit voltage to the vicinity including the closed circuit voltage. The calculation unit 33 sets the acquisition range to around 5.0V. The calculation unit 33 sets the width of the acquisition range to a value smaller than the range width a. Thereby, a power fault can be detected with high accuracy.

### Third Embodiment

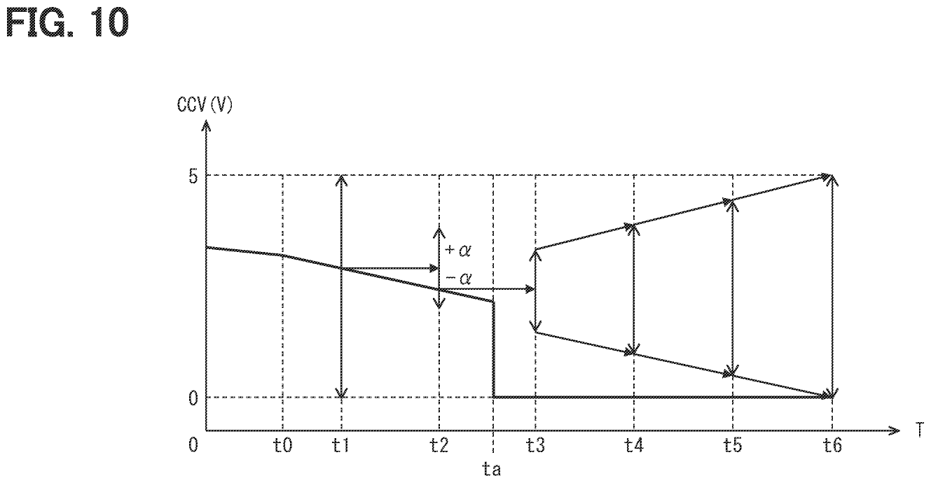

Next, a third embodiment will be described with reference to FIG. 10.

In the first embodiment, when the closed circuit voltage of the upper limit value or the lower limit value of the acquisition range is acquired, the calculation unit 33 resets the acquisition range of the closed circuit voltage to a possible range of the closed circuit voltage. On the other hand, in this embodiment, each time the closed circuit voltage of the upper limit value or the lower limit value of the acquisition range is acquired, the calculation unit 33 gradually expands the acquisition range of the closed circuit voltage as shown in FIG. 10.

### Fourth Embodiment

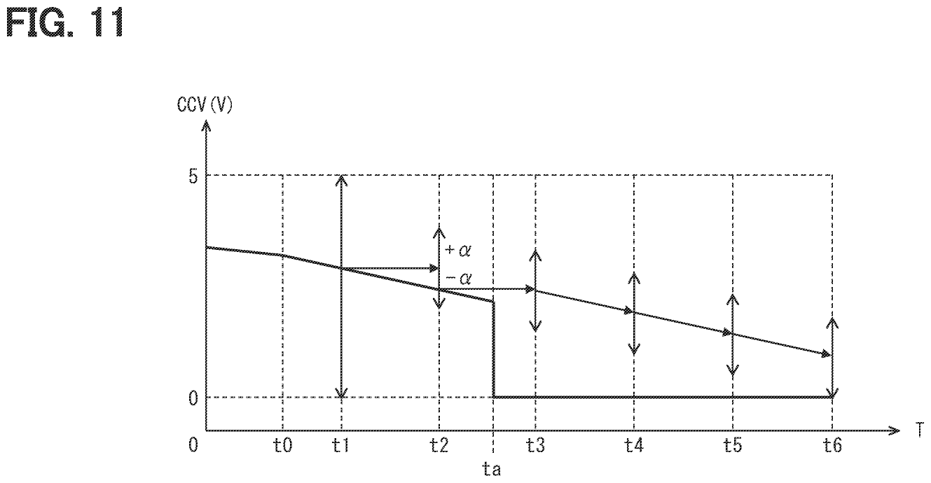

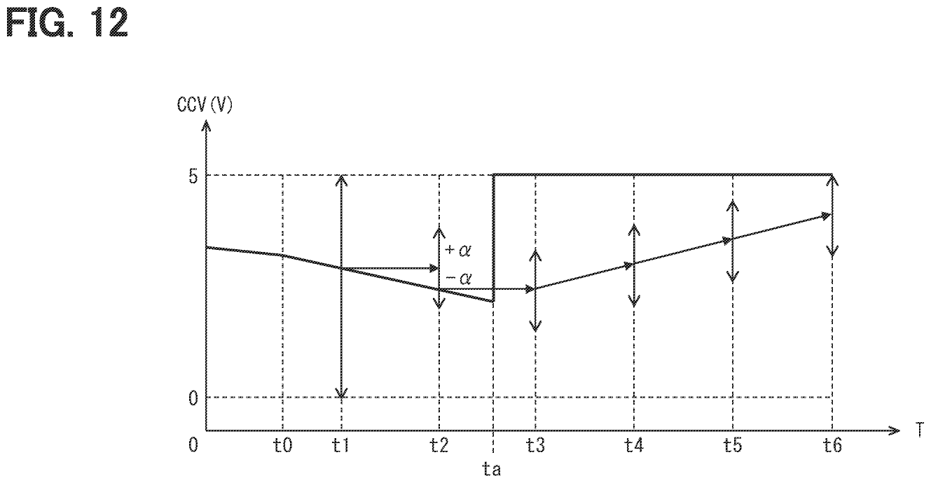

Next, a fourth embodiment will be described with reference to FIGS. 11 and 12.

In the second embodiment, the calculation unit 33 gradually expands the acquisition range of the closed circuit voltage every time the closed circuit voltage of the upper limit value or the lower limit value of the acquisition range is acquired. In contrast, in the present embodiment, each time the closed circuit voltage at the lower limit of the acquisition range is acquired, the calculation unit 33 gradually shifts the acquisition range of the closed circuit voltage to 0.0 V as shown in FIG. 11. Each time the closed circuit voltage of the upper limit value of the acquisition range is acquired, the calculation unit 33 gradually shifts the acquisition range of the closed circuit voltage to 5.0 V as shown in FIG. 12.

The calculation unit 33 determines that a ground fault has occurred when 0.0V is obtained in the acquisition range including 0.0V. When the calculation unit 33 obtains 5.0V in the acquisition range including 5.0V, it determines that a power fault has occurred.

### Fifth Embodiment

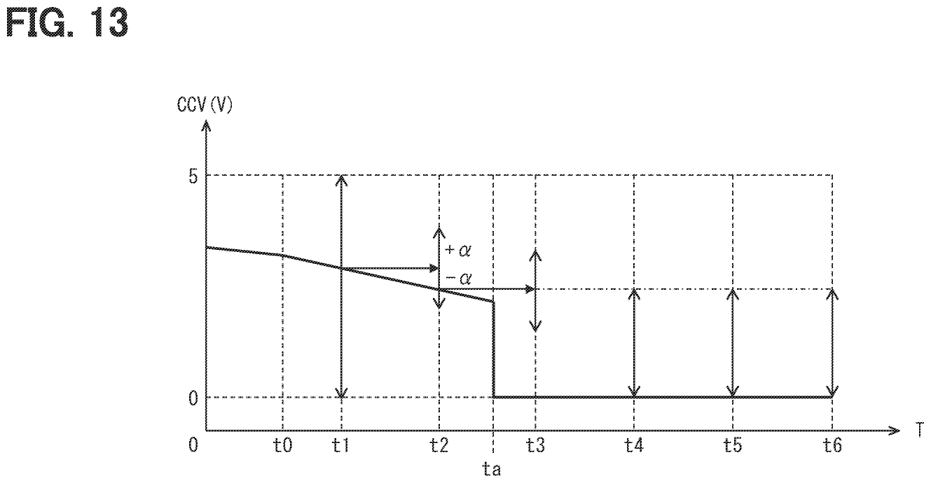

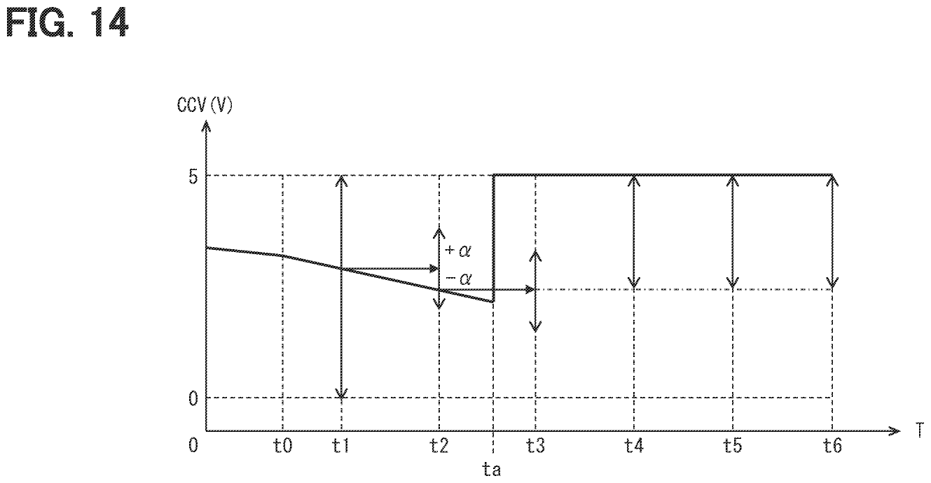

Next, a fifth embodiment will be described with reference to FIGS. 13 and 14.

In the first embodiment, when the closed circuit voltage of the upper limit value or the lower limit value of the acquisition range is acquired, the calculation unit 33 resets the acquisition range of the closed circuit voltage to a possible range of the closed circuit voltage. On the other hand, in this embodiment, when the closed circuit voltage is the upper limit value or the lower limit value of the acquisition range, the calculation unit 33 sets the acquired closed circuit voltage to the new lower limit value or upper limit value of the acquisition range.

When the closed circuit voltage is the lower limit value of the acquisition range, the calculation unit 33 sets the upper limit value of the new acquisition range to the acquired closed circuit voltage, as indicated by the dashed-dotted line in FIG. 13. Then, the calculation unit 33 sets the lower limit value of the new acquisition range to the lower limit value of the possible range.

When the closed circuit voltage is the upper limit value of the acquisition range, the calculation unit 33 sets the lower limit value of the new acquisition range to the acquired closed circuit voltage, as indicated by the dashed-dotted line in FIG. 14. Then, the calculation unit 33 sets the upper limit value of the new acquisition range to the upper limit value of the possible range.

According to this, deterioration in detection accuracy of the closed circuit voltage due to resetting of the acquisition range is suppressed.

### Other Modifications

In this embodiment, an example is shown in which one control unit 30 is provided for a plurality of monitor units 10. Alternatively, a configuration in which a plurality of controllers 30 are provided individually for a plurality of monitor units 10 may also be adopted.

In this embodiment, an example of setting the acquisition range of the closed circuit voltage of each of the plurality of battery cells 220 has been described. Alternatively, it may be also possible to employ a configuration in which the acquisition range of the closed circuit voltage of each of the plurality of battery stack 210 is set. It may be also possible to employ a configuration in which a common closed circuit voltage acquisition range is set for each of the plurality of battery cells 220 included in one battery stack 210. In such a modification, the assembled battery 200 has at least two battery stacks 210.

Although the present disclosure has been described in accordance with the embodiment, it is understood that the present disclosure is not limited to the embodiment and the structure. To the contrary, the present disclosure is intended to cover various modification and equivalent arrangements. In addition, while various combinations and modes are described in the present disclosure, other combinations and modes including only one element, more elements, or less elements therein are also within the scope and spirit of the present disclosure.

The controllers and methods described in the present disclosure may be implemented by a special purpose computer created by configuring a memory and a processor programmed to execute one or more particular functions embodied in computer programs. Alternatively, the controllers and methods described in the present disclosure may be implemented by a special purpose computer created by configuring a processor provided by one or more special purpose hardware logic circuits. Alternatively, the controllers and methods described in the present disclosure may be implemented by one or more special purpose computers created by configuring a combination of a memory and a processor programmed to execute one or more particular functions and a processor provided by one or more hardware logic circuits. The computer programs may be stored, as instructions being executed by a computer, in a tangible non-transitory computer-readable medium.

It is noted that a flowchart or the processing of the flowchart in the present application includes sections (also referred to as steps), each of which is represented, for instance, as S10. Further, each section can be divided into several sub-sections while several sections can be combined into a single section. Furthermore, each of thus configured sections can be also referred to as a device, module, or means.

What is claimed is:

1. A battery device comprising:
a storage unit that stores battery information including a closed circuit voltage of a plurality of battery cells electrically connected to each other;
a setting unit that sets an acquisition range of the closed circuit voltage based on the battery information; and
a conversion unit that converts the closed circuit voltage into a digital signal within the acquisition range set by the setting unit, wherein:
the setting unit changes the acquisition range when the closed circuit voltage is one of an upper limit value and a lower limit value of the acquisition range.

2. The battery device according to claim 1, wherein:
the setting unit expands the acquisition range when the closed circuit voltage is one of the upper limit value and the lower limit value of the acquisition range.

3. The battery device according to claim 2, wherein:
the setting unit changes the acquisition range to a possible range that the closed circuit voltage can take when the closed circuit voltage is one of the upper limit value and the lower limit value of the acquisition range.

4. The battery device according to claim 3, wherein:
the setting unit changes the acquisition range to a limited range including one of an upper limit value and a lower limit value of the possible range when the acquisition range is the possible range, and the closed circuit voltage is one of the upper limit value and the lower limit value of the possible range.

5. The battery device according to claim 1, wherein:
the setting unit changes the acquisition range to a new range shifted to a closed circuit voltage side when the closed circuit voltage is one of the upper limit value and the lower limit value of the acquisition range.

6. The battery device according to claim 1, wherein:
the setting unit sets the lower limit value of the acquisition range to the closed circuit voltage as a new lower limit value when the closed circuit voltage is the upper limit value of the acquisition range; and
the setting unit sets the upper limit value of the acquisition range to the closed circuit voltage as a new upper limit value when the closed circuit voltage is the lower limit value of the acquisition range.

7. The battery device according to claim 1, wherein:
the setting unit determines that a failure occurs when the closed circuit voltage is one of the upper limit value and the lower limit value of the acquisition range multiple times.
